(19) United States
(12) Patent Application Publication
(10) Pub. No.: US 2010/0310767 A1
(43) Pub. Date: Dec. 9, 2010

(54) VAPOR DEPOSITION APPARATUS AND VAPOR DEPOSITION METHOD

(75) Inventor: Atsuhiro Abe, Miyagi (JP)

Correspondence Address: SNR DENTON US LLP, P.O. BOX 061080, CHICAGO, IL, 60606-1080, US

(73) Assignee: SONY CORPORATION, Tokyo (JP)

(21) Appl. No.: 12/781,064

(22) Filed: May 17, 2010

(30) Foreign Application Priority Data
Jun. 4, 2009 (JP) 2009-134639

(51) Int. Cl. C23C 16/458; C23C 16/00

(52) U.S. Cl. 427/255.5; 118/718

(57) ABSTRACT

A vapor deposition apparatus includes: a vacuum tank; an exhaust section that performs vacuum exhaust in the vacuum tank; a vapor deposition source disposed in the vacuum tank to vaporize a deposition material; and a traveling path for allowing an elongated substrate on which the deposition material is deposited to travel along a concave path with respect to the vapor deposition source at least in a region opposing the vapor deposition source.

### BACKGROUND OF THE INVENTION

1. Field of the Invention

The present invention relates to a vapor deposition apparatus and vapor deposition method which deposit a film on an elongated substrate.

2. Description of the Related Art

In case where of forming a thin film on a soft substrate, such as a plastic film or metal foil, by vacuum deposition, a winding type vapor deposition apparatus has been used in the past. FIG. 12 is a configurational diagram showing this winding type vapor deposition apparatus 300.

The winding type vapor deposit ion apparatus 300 according to the related art has a vacuum tank 61 and a vacuum pump 62 to vacuum inside the vacuum tank 61. Provided in the vacuum tank 61 are a cooling roller 67 which cools a substrate 66 along the periphery thereof at the time of vapor deposition, a roller 71 which winds out the substrate 66 before vapor deposition, a roller 72 which winds up the substrate 66 after vapor deposition, and guide rollers 69 which guide the traveling path of the substrate 66. A vapor deposition source 63 which vaporizes a deposition material is disposed under the cooling roller 67.

The substrate 66 wound out in the direction of an arrow A5 by the roller 71 travels along the lower portion of the cooling roller 67 via the guide rollers 69. The deposition material vaporized from a melting pot 65 in the vapor deposition source 63 disposed under the cooling roller 67 rises as vapor flows 64 to be deposited on the substrate 66 traveling along the cooling roller 67 from below. After vapor deposition, the substrate 66 is wound up in the direction of an arrow A6 by the roller 72.

The cooling roller 67 is configured so that a coolant, such as cool water, circulates inside to absorb radiation heat received by the substrate 66 and latent heat of the deposited film at the time of vapor deposition, thereby cooling the substrate 66.

As apparent from the above, the related art has the structure such that vapor deposition is carried out with the substrate 66 traveling in vacuum while its back side opposite the vapor deposition surface is in contact with the cooling roller 67. That is, at a deposition start point 67a when vapor deposition on the substrate 66 starts, a vapor flow 64a has an angle of incident to the traveling direction of the substrate 66 from an oblique direction E1 from the front side. At a deposition end point 67b, a vapor flow 64b has an angle of incident to the traveling direction of the substrate 66 from an oblique direction E2, substantially opposite to the direction E1, from the rear.

The state of the film formed by vapor deposition normally has a column structure as shown in FIG. 13, depending on the temperature or the like of the substrate. Due to the aforementioned positional relation with the melting pot 65, a growth direction e1 corresponding to the incident direction E1 of the vapor flow 64a at the cooling roller 67 differs from a growth direction e2 corresponding to the incident direction E2 of the vapor flow 64b at the deposition end point 67b. As a result, a column structure 113 formed is bent to have gaps 121 between columns. When there is such an askew incident component to the substrate 66, particularly, so-called shadowing occurs which forms shadow portions by the irregularities of the substrate 66 or the film surface, also forming gaps 122 there to reduce the film density. In case of multilayer deposition, gaps are formed between layers.

The presence of such gaps 121, 122 causes oxidation therefrom in case of a magnetic tape, deteriorating the characteristic thereof. In case of an optical thin film or the like, the reflectance changes with time, causing the wavelength shift. Further, the presence of such gaps causes a time-dependent change or reduction in characteristic incase of semiconductor device, an electronic device and so forth.

One way to suppress occurrence of such gaps is to mount an incident angle regulating plate 80 on the vapor deposition source 63 side of the cooling roller 67 as shown in FIG. 12. When the incident angle of the vapor flows 64 to the substrate 66 is restricted in this way, however, the deposition rate is reduced, lowering the material efficiency. In addition, vapor deposition for a long period of time adheres the deposition material to the end portion of the incident angle regulating plate 80, changing the incident angle. It is therefore necessary to maintain the incident angle regulating plate 80 every given period, and perform delicate adjustment in consideration of a change in incident angle.

Japanese Patent No. 3529922 (Patent Document 1) discloses the structure that has a region provided to allow a substrate to linearly travel on an auxiliary belt between two rollers, and performs vapor deposition in the region. JP-A-10-226877 (Patent Document 2) proposes a method of providing a region for likewise allowing a substrate to linearly travel, and scattering a deposition material from both sides of the substrate.

### SUMMARY OF THE INVENTION

The deposition angle condition can be controlled to some extent by allowing a substrate to linear travel as proposed in Patent Documents 1 and 2. In this case, however, there still is a difference between the deposition angles at the deposition start point and the deposition end point. Accordingly, while the difference in the growth direction from the beginning of the growth of the column to the end thereof in the example shown in FIG. 13, occurrence of gaps cannot be avoided, thus still leading to reduction in film density.

Accordingly, it is desirable to provide a vapor deposition apparatus and vapor deposition method which can perform high-density film deposition with occurrence of gaps suppressed.

According to an embodiment of the present invention, a vapor deposition apparatus has a vacuum tank, an exhaust section that performs vacuum exhaust in the vacuum tank, and a vapor deposition source disposed in the vacuum tank to vaporize a deposition material. Further, the vapor deposition apparatus has a traveling path for allowing an elongated substrate on which the deposition material is deposited to travel along a concave path with respect to the vapor deposition source at least in a region opposing the vapor deposition source.

According to another embodiment of the invention, a vapor deposition method includes a substrate holding step of holding an elongated substrate along a concave path with respect to a vapor deposition source at least in a region opposing the vapor deposition source. The vapor deposition method further includes a vapor deposition step of scattering a deposition material from the vapor deposition source to perform vapor deposition on the substrate while causing the substrate to travel along the path.

The vapor deposition apparatus according to the embodiment of the invention allows a substrate to travel along the concave path with respect to the vapor deposition source, and scatters the deposition material radially from the vapor deposition source to thereby reduce the difference in deposition direction in the region from the deposition start point to the deposition end point.

That is, the substrate is allowed to travel along the concave path with respect to the vapor deposition source, thus making it possible to set the incident angle to the substrate to lie in a narrower range even with a vapor flow which expands laterally. This makes it possible to suppress the amount of a change in column in the growth direction at the time of the growth of the column, thereby suppressing occurrence of gaps.

According to the embodiments of the invention, vapor flows obliquely incident to a substrate are reduced, so that a high-density film can be deposited.

### BRIEF DESCRIPTION OF THE DRAWINGS

FIG. 1 is a schematic configurational diagram of a vapor deposition apparatus according to a first embodiment of the present invention;

FIG. 2 is an exemplary cross-sectional view showing the column structure of a thin film which is deposited by the vapor deposition apparatus according to the embodiment;

FIG. 3 is a diagram showing the relation between the amount of heat absorbed by a cooling roller and the traveling speed of a substrate;

FIG. 4 is a diagram showing the relation between the amount of heat generated from the substrate and the traveling speed of the substrate;

FIG. 5 is an explanatory diagram showing a substrate undergone film deposition by a vapor deposition apparatus according to the related art;

FIG. 6 is an explanatory diagram showing a substrate undergone film deposition by the vapor deposition apparatus according to the embodiment of the invention;

FIG. 7 is an enlarged cross-sectional view showing a film deposited by the vapor deposition apparatus according to the related art and photographed by a scanning electron microscope;

FIG. 8 is an enlarged cross-sectional view showing a film deposited by the vapor deposition apparatus according to the embodiment and photographed by a scanning electron microscope;

FIG. 9 is a schematic configurational diagram of a vapor deposition apparatus according to a second embodiment of the invention;

FIG. 10 is an explanatory diagram showing a substrate undergone film deposition by the vapor deposition apparatus according to the second embodiment of the invention;

FIG. 11 is a schematic configurational diagram of a vapor deposition apparatus according to the second embodiment of the invention;

FIG. 12 is a schematic configurational diagram of one example of the vapor deposition apparatus according to the related art; and

FIG. 13 is an exemplary cross-sectional view showing the column structure of a thin film which is deposited by the vapor deposition apparatus according to the related art.

### DESCRIPTION OF THE PREFERRED EMBODIMENTS

Vapor deposition apparatuses and vapor deposition methods according to preferred embodiments of the present invention will be described below, with are not restrictive in any ways. The description will be given in the following order.

1. First Embodiment of Vapor Deposition Apparatus and Vapor Deposition Method

(1) Configuration of Vapor Deposition Apparatus

(2) Steps of Vapor Deposition Method

(3) Example

a. Cooling Amount for Substrate

b. Appearance and Cross-sectional Structure After Deposition

2. Second Embodiment of Vapor Deposition Method

3. Second Embodiment of Vapor Deposition Apparatus

### 1. First Embodiment of Vapor Deposition Apparatus and Vapor Deposition Method

### (1) Configuration of Vapor Deposition Apparatus

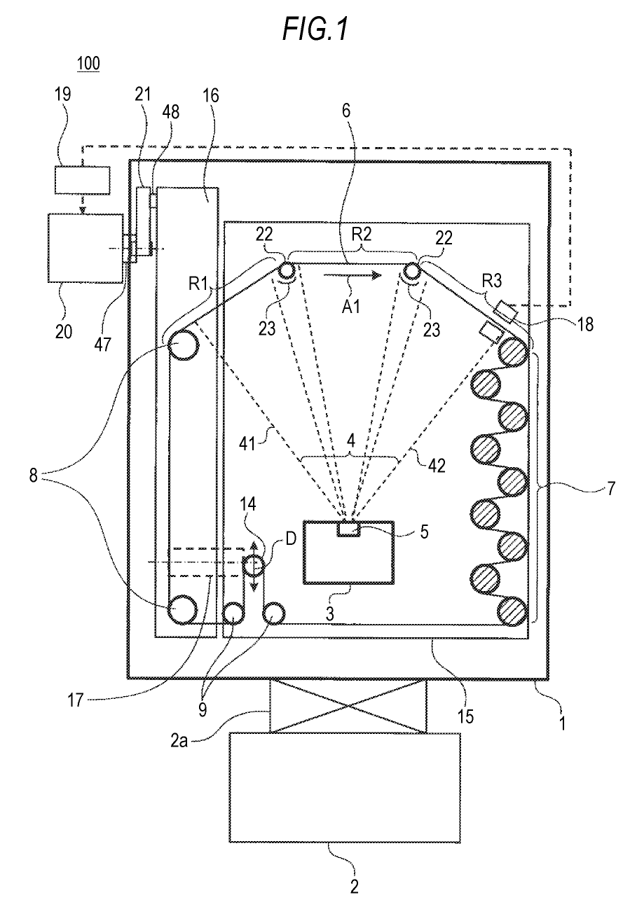

FIG. 1 is a schematic configurational diagram of a vapor deposition apparatus 100 according to the first embodiment. The vapor deposition apparatus 100 according to the embodiment has a vacuum tank 1, and a vacuum pump 2 as an exhaust section that vacuums inside the vacuum tank 1. The vacuum tank 1 is vacuumed to, for example, 10⁻² to 10⁻⁴ Pa by the vacuum pump 2 connected thereto via a valve 2a.

Rollers 22 which define a concave traveling path with respect to a melting pot 5 of a vapor deposition source 3 are disposed at positions at substantially equal distances obliquely upward from the melting pot 5 of the vapor deposition source 3. The rollers 22 preferably have smaller diameters than other guide rollers or cooling rollers. A plurality of cooling rollers 7 having a cooling capability are disposed frontward in the traveling direction of the substrate 6 to be held. The cooling rollers 7 are arranged on a fixed base plate 15 up and down alternately in a zigzag fashion from the obliquely upper side to the obliquely lower side with respect to the vapor deposition source 3. Further, guide rollers 9 and a dancer roller 14 are disposed in the vicinity of the lower end of the opposite side of the fixed base plate 15 to the end side of the cooling rollers 7 with the vapor deposition source 3 in between. A movable base plate 16 having a rectangular planar shape is disposed adjacent to the fixed base plate 15. The movable base plate 16 has guide rollers 8 at an upper portion thereof and at a position close to the guide rollers 9 on the end side of the traveling direction. The guide rollers 8, the rollers 22 defining the concave traveling path, the cooling rollers 7, the guide rollers 9 and the dancer roller 14 form a traveling path with a closed curve shape.

In the example in FIG. 1, the dancer roller 14 is provided between the two guide rollers 9 disposed on the traveling path of the substrate 6. The dancer roller 14 is coupled to a drive mechanism (not shown) which smoothly slides or takes a circular motion in a direction intersecting the top surface of the substrate 6, for example, in the direction of an arrow D substantially orthogonal to the top surface. With force applied in the direction away from the path by an unillustrated spring, weight, air cylinder or the like, the dancer roller 14 moves to partially lift up or down the substrate 6 between the guide rollers 9. The overall tension on the substrate 6 is adjusted by providing the guide rollers 9 and moving the positions thereof in a direction away from the traveling path or a direction closer thereto.

The movable base plate 16 on which the guide rollers 8 are provided is rotatably fastened to the fixed base plate 15 having the rollers 22, the cooling rollers 7, the guide rollers 9, etc. provided thereon via a rotary shaft 17 at a lower end of the movable base plate 16.

A rotary shaft 47 of a motor 20 provided outside the vacuum tank 1 is placed in the vacuum state in the vacuum tank 1, and is connected to an arm 21. The arm 21 is fastened to the upper end of the movable base plate 16 by a link mechanism, such as a shaft 48. Accordingly, the forward/reverse rotation of the motor 20 allows the movable base plate 16 to tilt about the rotary shaft 17 with a lateral direction to the traveling direction of the of the substrate 6 or a direction perpendicular to the sheet surface of FIG. 1 being a tangential direction.

In this example, an edge sensor 18 is provided on any point on the traveling path of the substrate 6. In the example in FIG. 1, the edge sensor 18 is disposed at the end of a traveling path R3 and a position directly before the cooling rollers 7. The arrangement of the edge sensor 18 is not limited to this example, and can be made at another position. The edge sensor 18 detects the edge position of the substrate 6 in the widthwise direction orthogonal to the traveling direction thereof to measure the amount of the widthwise shift of the substrate 6. The measured amount of shifting is input to a controller 19. The controller 19 sends the motor 20 a signal to rotate the motor 20 in the forward or reverse direction based on the shift amount.

Accordingly, the shift of the traveling path of the substrate 6 in the widthwise direction thereof is detected immediately, and can be corrected by the tilt motion of the movable base plate 16 about the rotary shaft 17. The vapor deposition apparatus 100 according to the embodiment can therefore minimize the meandering of the substrate 6.

The number and arrangement of the rollers 22 forming the concave traveling path are not limited to those of the example. It is however preferable that as shown in FIG. 1, the rollers 22 should be disposed substantially at equal distances to the melting pot 5, and off the position directly above the melting pot 5 for the following reason. Because the rollers 22 are disposed on the vapor deposition side to the substrate 6, a deposition material is adhered to the rollers 22, so that it is desirable to avoid falling of the material separated from the rollers 22 onto and around the melting pot 5. To suppress adhesion of the deposition material to the rollers 22 and facilitate maintenance for removal of the adhered matter, it is preferable to provide cover members 23 at the rollers 22 on the vapor deposition source 3 side.

In addition, the numbers and arrangements of the guide rollers 8, 9 and the dancer roller 14 are not limited to those of the example, and their quantities may be increased.

The cooling rollers 7 are not limited to the illustrated example, and the number thereof may be increased. For example, the cooling rollers 7 may be disposed in a line, not in an alternate zigzag pattern as exemplified in FIG. 1. It is however preferable to dispose the cooling rollers 7 in such a way that both sides of the substrate 6 can contact the individual rollers 7. It is more preferable to dispose cooling rollers 7 in such a way that the top surface and the back surface of the substrate 6, i.e., the deposition surface and the back surface alternately contact the cooling rollers 7. As both sides of the substrate 6 can be cooled, efficient cooling of the substrate 6 can be achieved. Particularly, the cooling efficiency can be improved by arranging the cooling rollers 7 so that both sides of the substrate 6 alternately contact the cooling rollers 7.

It is preferable to have the general layout positions of the cooling rollers 7 in such a way that the cooling rollers 7 are disposed closest to a last deposition region R3 in deposition regions R1 to R3. This arrangement can allow the substrate 6 to be cooled quickly from both sides immediately after vapor deposition on the substrate 6 is carried out for a given time. The time from the end of vapor deposition to the beginning of the cooling process is determined by setting the traveling speed of the substrate 6 and the layout pitches of the cooling rollers 7.

In case where a deposition material is vaporized beyond traveling regions R1 to R3 where vapor deposition is performed, a shielding member may be provided between the melting pot 5 and the individual guide rollers 8 and cooling rollers 7, though not illustrated, to suppress adhesion of the deposition material to parts of the guide rollers 8 or the cooling rollers 7. Further, cover members may be additionally provided for some of the rollers.

According to the embodiment, as shown in FIG. 1, the traveling direction of the substrate 6 is changed in the traveling paths R1, R2, R3 where vapor deposition on the substrate 6 is performed.

Normally, the rising of the vapor flows 4 of vapor from the melting pot 5 has the directional characteristic; for example, vapor flows 41 and 42 which flow toward the guide rollers 8 and the cooling rollers 7 rise laterally spreading as well as vertically. According to the embodiment, the two rollers 22 are disposed in the traveling path where vapor deposition occurs, this traveling path is divided into the directions of R1, R2 and R3. In this case, the substrate 6 travels in the air between a plurality of rollers 22 to be subjected to vapor deposition, so that stress applied onto the substrate 6 at the time of vapor deposition becomes easier to escape, thus making it possible to suppress the amount of deformation as compared with the case of cooling the back surface at the same time the vapor deposition is performed.

In this case, although the substrate 6 travels linear in each traveling path R1, R2 or R3, the traveling paths R1, R2, R3 are arranged so as to be concave with respect to the vapor deposition source 3. This makes the incident angle of the deposition material to the deposition surface of the substrate 6 closer to the vertical direction in each region than the one in the related art. Therefore, a change in incident angle can be suppressed, i.e., the oblique incident component of the vapor flow can be reduced.

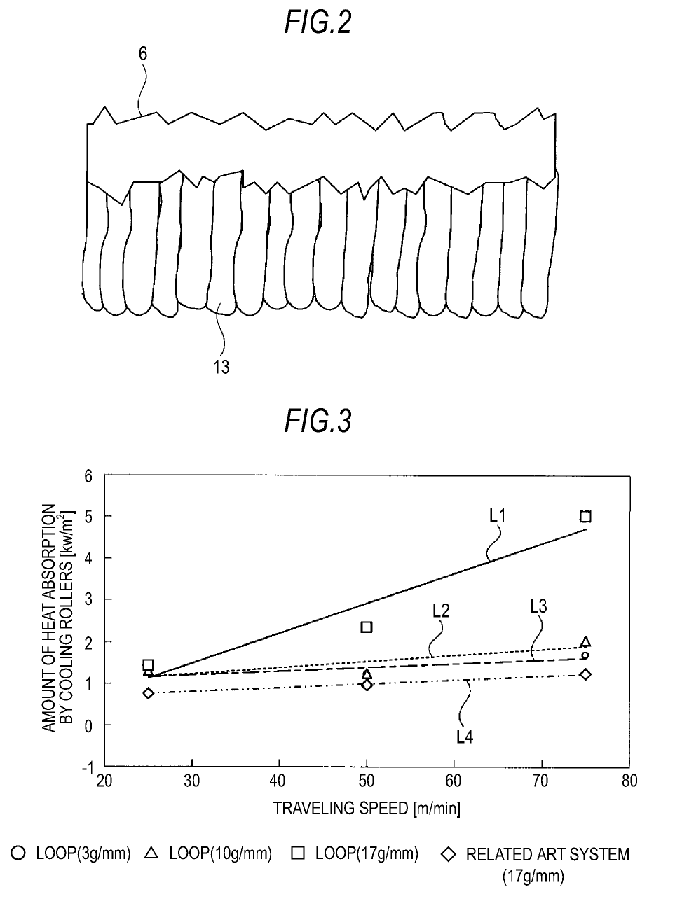

The reduction in the oblique incident component of the vapor flow can decrease the portion thereof which places a shadow on the minute undulations of the substrate 6 in the deposition direction, thus suppressing the shadowing phenomenon, which is shown in an exemplary cross-sectional view in FIG. 2. In this case, as shown in FIG. 2, a column structure 13 which hardly has gaps can be formed to ensure high-density film deposition. Therefore, the poorer the degree of roughness of the surface of the substrate is, the more shadowing can be suppressed by this scheme of performing vapor deposition while causing the substrate 6 to travel in a concave path. The scheme reduces occurrence of gaps, and is thus more effective.

In addition, the vapor deposition apparatus 100 according to the embodiment can allow the substrate 6 to travel in a closed curve pattern at a relatively high speed, and ensure repetitive lamination of thin films gradually. It is preferable to set the traveling speed to twice or faster than the traveling speed involved in the case of achieving an intended film thickness by a single vapor deposition. Performing vapor deposition multiple times in closed curve traveling can make the growth direction of the column uniform in the traveling path R1, R3 which extends in a slightly oblique direction. This can further reduce the bending of the column structure to obtain a deposited film with a higher density.

Further, the vapor deposition apparatus 100 according to the embodiment performs vapor deposition in the traveling paths R1 and R3, and can use vapor flows 41a, 41b which greatly spread laterally for vapor deposition. This can enhance the use efficiency of the deposition material almost three times the efficiency in the case of performing vapor deposition only in the traveling path R2.

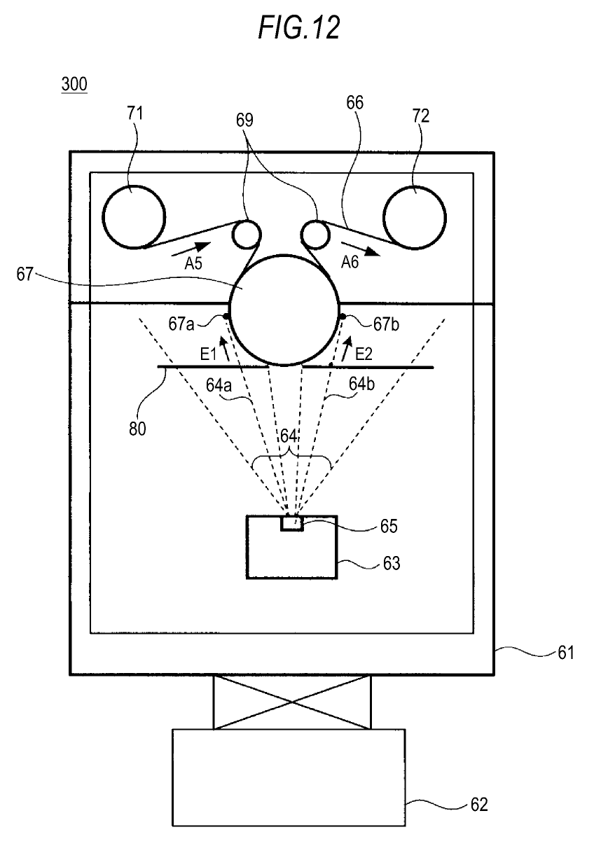

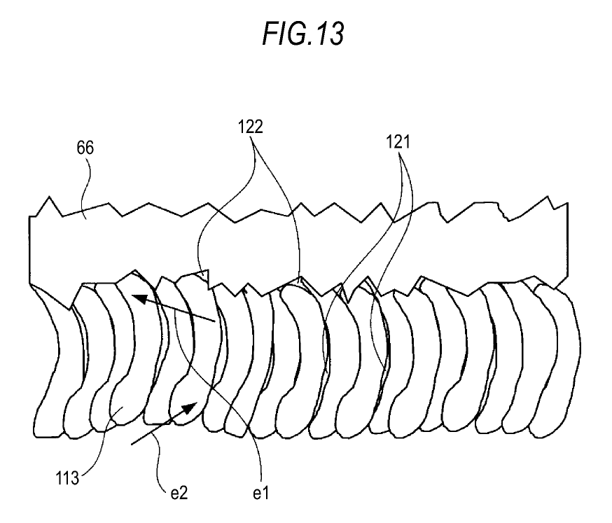

In case where the deposition angle to the substrate 6 is restricted by the incident angle regulating plate 80 as shown in FIG. 12, for example, the ratio of the deposition material to be deposited on the substrate 6 is as low as 10 to 200 of the scattering material. By way of contrast, the ratio is improved to 20 to 40% according to the embodiment, which can lead to cost reduction.

With the degree of vacuum set in the vacuum tank 1 in the above case, the vapor flows 4 from the melting pot 5 travel almost linearly. Therefore, the incident direction of the deposition material lies in a certain range in each of the traveling paths R1 to R3. To set the range of the incident angle as perpendicular as possible, it is preferable to arrange the traveling paths R1 to R3 in such a way that the plane normal lines drawn from the 5 to the substrates 6 on the traveling paths R1 to R3 intersect the center positions of the traveling paths R1 to R3.

To achieve the arrangement, the first rollers of the guide rollers 8 and the cooling rollers 7 which contribute to the formation of the concave traveling path should be arranged at equal distances from the melting pot 5. This allows the vapor flows to be perpendicularly incident to the substrate 6 at the center positions of the traveling paths R1 to R3.

As the number of the path segments is increased to make the traveling path in an annular curved surface about the melting pot 5, a better effect is obtained. However, it is preferable to provide the roll covers 23 at the rollers 22 to prevent the deposition material from being adhered thereto as mentioned above. Therefore, increasing the number of the rollers 22 to make the path closer to a curved surface reduces the area of the substrate in the path which can be used for vapor deposition by the increased number of the roll covers. This reduces the use efficiency of the deposition material, so that it is not preferable to increase the number of path segments to more than necessary. According to the embodiment, the number of paths is three, for example, and it is preferable to set the number of paths to 10 or less in consideration of the use efficiency of the deposition material.

The substrate 6 which has undergone vapor deposition in the traveling paths R1 to R3 travels while being held by the cooling rollers 7 arranged in the aforementioned alternately zigzag fashion. This can allow the substrate 6 to be cooled from both sides, thus ensuring a high cooling effect.

The cooling rollers 7 are configured in such a way that at least the top surface of the cooling roller 7 is made of a material having a high thermal conductivity, e.g., plated with hard chrome, and is connected with a rotary joint in which a coolant is circulated. It is preferable to perform temperature adjustment using a cooling/heating medium unit (not shown). The cooling roller 7 is normally configured to seal a coolant inside, and therefore has a rotational resistance. It is therefore preferable to drive all of the plurality of cooling rollers by an unillustrated motor provided separately. Driving all the rollers in this manner can reduce the stress applied onto the substrate 6 at the time of traveling.

The vapor deposition apparatus 100 according to the embodiment cools the substrate 6 from both sides and deposit multiple layers repeatedly at a high speed, thereby significantly reducing the thermal load. This can ensure high-rate film deposition and improve the productivity as well as achieve high-quality film deposition with less deformation or residual stress of the substrate.

With the thermal load reduced, it is possible to form a film of a high melting point material or a low vapor pressure material, such as oxide, which has been formed only by sputtering and has been difficult to be formed by vapor deposition in the past.

### (2) Steps of Vapor Deposition Method

Next, steps performed in vapor deposition using the vapor deposition apparatus 100 will be described.

First, an elongated substrate 6 is disposed with a predetermined tension around and outside the individual rollers in the traveling path formed in the closed curve pattern. That is, the elongated substrate 6 is disposed along and outside the individual rollers 8, 9, 22 and 7 first, and has both ends connected together into a closed curve pattern by adhesion, welding or the like. As the individual rollers or some of the rollers are rotated, the endless substrate 6 is guided on the traveling path restricted by the rollers to be able to travel in an endless manner as indicated by an arrow A1 (clockwise in the example in FIG. 1) at a predetermined speed.

The vapor deposition source 3 is disposed inward of the substrate 6 arranged in the closed curve pattern. The vapor deposition source 3 may be provided with a moving unit (not shown) so as to be disposed at a predetermined position as needed after the mounting of the substrate 6 is completed. The melting pot 5 in the vapor deposition source 3 is heated or so to vaporize the deposition material. In the traveling regions R1 to R3 where the substrate 6 is moved in a concave pattern by the rollers 22, the vapor flows 4 which are scattered in a fan shape or an eye drop pattern are vapor-deposited on the inner surface of the substrate 6 arranged in a concave shape.

According to the embodiment, a belt-like plastic film, a metal foil of stainless, aluminum or the like, or the lamination of the film and metal foil, or any elongated material which can have both ends connected together in loop, such as paper or cloth, can be adopted as the substrate 6.

Various materials including a high melting point metal, such as Si, an oxide, and a Co-based magnetic material, can be used as the deposition material.

Vaporization of the deposition material can be achieved by heating the melting pot 5 or other various methods, such as irradiation of a laser beam or an electron beam.

### (3) Example

### a. Cooling Amount for Substrate

FIG. 3 is a diagram showing the relation between the amount of heat absorbed by the cooling roller and the traveling speed of a substrate when Si is vapor-deposited on the substrate of Cu, which has a thickness of 30 μm, a ten point height of irregularities Rz of 2 μm. A solid line L1, a broken line L2, and a one-dot chain line L3 respectively show cases where films are formed on the substrate with tensions of 3 g/mm, 10 g/mm and 17 g/mm applied thereto using the vapor deposition apparatus 100 according to the embodiment. In this example, the number of the cooling rollers 7 is set to six. The diameter of the cooling roller 7 is 60 mmφ, and the vapor deposition apparatus 100 configured to have a hard chrome film provided on the top surface of the roller of aluminum has a width and height of about 1 m. A two-dot chain line L4 represents a case where film deposition on a similar substrate is performed with tension of 17 g/mm using the vapor deposition apparatus 300 according to the related art which has been explained referring to FIG. 12. The amount of heat absorption is calculated from the difference between the temperature of the cooling water fed to the cooling rollers 7, 67 and the temperature of the cooling water when the cooling water is discharged from the cooling rollers.

It is apparent from the lines L1 to L3 showing the results of film deposition using the vapor deposition apparatus 100 according to the embodiment that the greater the tension applied to the substrate, the greater the amount of heat absorption, providing a high cooling effect. It is therefore preferable to increase the tension within the range where breaking or the like of the substrate does not occur. In addition, it is apparent that the higher the traveling speed of the substrate, the higher the amount of heat absorption, and that the greater the tension applied to the substrate, the more prominent this effect.

It is apparent from the results in FIG. 3 that when the tension exceeds 10 g/mm, the ratio of the increase of the amount of heat absorption in proportion to the traveling speed increases. In case of a substrate and a deposition material which have a problem of thermal deformation or the like at the time of vapor deposition, therefore, it is preferable to set the tension to exceed 10 g/mm to be about 17 g/mm, thereby increasing the traveling speed. Because the traveling path is provided in the closed curve pattern according to the embodiment, if the traveling speed is increased, a thin film with a predetermined thickness can be formed easily by performing film lamination multiple times.

When a film is formed by a single vapor deposition as done in the method according to the related art, however, an increase in the amount of heat absorption cannot be seen much even if the traveling speed of the substrate is increased. If the traveling speed is made faster to increase the amount of heat absorption as much as possible, the amount of heat applied to the deposition material is increased, so that the amount of film deposition on the substrate should be compensated by increasing the vapor pressure. The method according to the related art therefore increases the thermal load to be applied to the substrate. That is, according to the method according to the related art, it is difficult to form a film of a high melting point material or a material with low vapor pressure on a low thermotolerant substrate.

By way of contrast, the method according to the embodiment can perform film deposition on a substrate multiple times or multiple film depositions while allowing the substrate to travel in the closed curve pattern at a faster speed than the speed of the related art. Accordingly, the thermal load to be applied to a substrate is divided by the number of film depositions, and cooling is repeated for each deposition of a film. This can reduce the thermal load to be applied to a substrate at a time.

When film deposition is performed under the tension on the substrate of 17 g/mm using the vapor deposition apparatus 300 according to the related art as indicated by the two-dot chain line L4, the amount of heat absorption is about 1 kW/m² at most. According to the embodiment, by way of contrast, it is apparent that heat absorption equal to or greater than the heat absorption indicated by the two-dot chain line L4 is already achieved at the level of the one-dot chain line L3 at which the tension on the substrate is 3 g/mm, and the cooling performance of 5 kW/m² is achieved at the level of the line L1 at which the tension on the substrate is equal to that of the line L4 by increasing the traveling speed.

In particular, it is preferable that film deposition should be performed by the vapor deposition apparatus 100 according to the embodiment at the traveling speed of 50 m/min or faster because at this traveling speed, the cooling effect as great as or higher than twice the cooling effect achieved by using the vapor deposition apparatus according to the related art is achieved. The faster the traveling speed, the lower the thermal load. This is because when the traveling speed is n times, the thermal load becomes 1/n. The upper limit of the traveling speed, which is restricted by the deposition speed, preferably takes such a value as to provide a film deposited to a certain thickness in a single vapor deposition process, and more preferably takes a value of about 200 m/min or less.

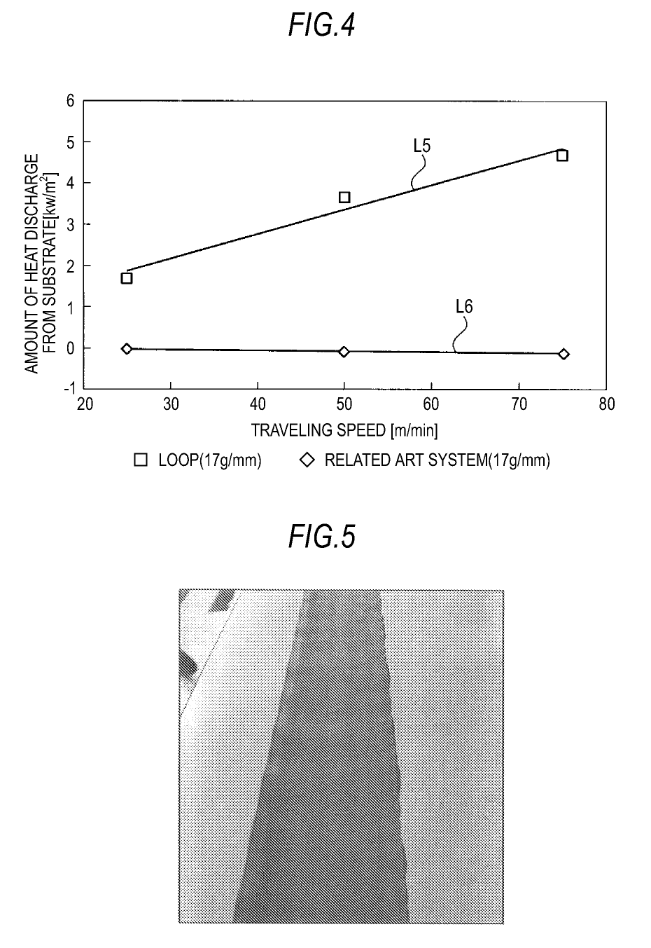

FIG. 4 shows a case where the temperatures of each substrate shown in FIG. 3 before and after intervention of the cooling rollers are measured, and the difference therebetween is acquired as the amount of heat absorbed from the substrate by the cooling rollers. In FIG. 4, a solid line L5 corresponds to the solid line L1 according to the embodiment in FIG. 3, and a solid line L6 corresponds to the two-dot chain line L4 which represents the method according to the related art in FIG. 3. The abscissa in FIG. 4, as in FIG. 3, represents the traveling speed of the substrate.

It is apparent from the comparison of the solid line L5 for the embodiment with the solid line L1 in FIG. 3 that the amount of heat absorption by the cooling rollers substantially coincides with the amount of heat discharged from the substrate. It can be said from this result that heat discharged from the substrate is efficiently absorbed by the cooling rollers according to the embodiment. This makes it easier to control the cooling of the substrate.

According to the solid line L6 for the method according to the related art, vapor deposition is performed on a substrate set along the cooling roller 67, so that the measured value becomes the difference between the temperatures of the substrate before and after vapor deposition. Accordingly, the value of the amount of heat becomes nearly zero on the solid line L6. From the fact that the amount of heat takes a negative value at a high traveling speed, it seems that slight heat remains on the substrate as a result of incomplete cooling. It is therefore apparent that the system according to the related art cannot catch up with the traveling speed as the traveling speed becomes faster.

The problem of such an insufficient cooling performance will be discussed below.

According to the general method of the related art, as in the vapor deposition apparatus 300 according to the related art shown in FIG. 12, the cooling roller 67 which guides a substrate 66 is configured so that a coolant, such as cool water, circulates inside to absorb radiation heat received by the substrate 66 and latent heat of the deposited film at the time of vapor deposition, thereby cooling the substrate 66. As apparent from the above, the related art has the structure such that vapor deposition is carried out with the substrate 66 traveling in vacuum while its back side opposite the vapor deposition surface is in contact with the cooling roller 67, i.e., heat is absorbed by the cooling roller 67 closely contacting the back side of the substrate at the same time vapor deposition is performed.

The aforementioned Patent Document 1 discloses that preheating of a substrate before vapor deposition is performed by an infrared lamp or the like. The preheating of the substrate is intended to prevent an abrupt rise in temperature of the substrate at the time of vapor deposition, thereby suppressing thermal deformation of the substrate.

The aforementioned Patent Document 2 discloses a method by which a solid raw material is disposed on both sides of a substrate, and is vaporized with irradiation of a laser beam to thereby form a thin film on both sides of the substrate. This restrains the difference between the temperatures of both sides of the substrate from increasing by a certain amount.

When vapor deposition is performed with the substrate 66 set in close contact with and along the cooling roller 67 in the above manner, heat is absorbed from the back side through the substrate 66, so that there is a limit to the amount of heat received by the cooling roller 67. This limits the thickness of a film to be deposited at a time. Particularly, a substrate susceptible to heat, such as a plastic film, needs to be cooled sufficiently, which requires that the deposition speed should be decreased, bringing about a prominent problem of reduction in film deposition rate. This problem also arises in case of using a substrate and deposition material with poor thermal conductivity, or a substrate which has a rough back surface and poor contact.

In case of a substrate with a high Young's modulus, such as a metal foil, besides a plastic film, slight bending of a substrate or positional deviation thereof with respect to the roller degrades the adhesion to the cooling roller 67, which may result in insufficient cooling. In this case, the substrate is deformed or deteriorated.

Since vapor deposition is performed in vacuum, heat is absorbed from the substrate 66 through heat conduction and radiation. However, the cooling roller 67 has the degree of its surface roughness reduced to have a mirror surface to increase the area of contact with the substrate 66, heat radiation from the substrate 66 is reflected. Therefore, the cooling roller 67 absorbs heat from the substrate 66 mostly through heat conduction.

This heat conduction is improved as the area of contact between the cooling roller 67 and the substrate 66 become larger. While the contact area depends on the pressure on the contact surfaces of both of the cooling roller 67 and the substrate 66, this pressure is a force component generated from the tension on the substrate 66 in the winding type vapor deposition apparatus 300, and has a small value.

Further, the tension which can be applied to the substrate 66 is limited by the strength and residual stress of the substrate, occurrence of wrinkles thereon, etc. Therefore, the tension value is small, and the force component becomes smaller as the diameter of the cooling roller 67 becomes larger, thus limiting the amount of heat which can be absorbed from the substrate 66 by the cooling roller 67.

According to the embodiment, by way of contrast, the back side of the substrate 6 does not contact anything in the vapor deposition region, so that heat escapes from the back side through heat radiation. Although cooling is performed immediately after vapor deposition, the deposition surface as well as the back surface of the substrate contacts each of the cooling rollers 7. This configuration seems to permit heat produced by vapor deposition to be absorbed through heat conduction more efficiently. The separation of the layout positions of the cooling rollers 7 from the deposition regions R1 to R3 can allow the diameter of the cooling rollers to be made smaller regardless of the vapor deposition area or the like. Accordingly, the pressure on the cooling rollers becomes adequate to make the cooling effect greater.

The cited Patent Document 1 discloses that a substrate before film deposition is irradiated with an electron beam to be charged up, thereby increasing the electrostatic-force originated adhesion to the cooling roller. However, this method is effective for an insulative substrate, but cannot be adopted to a conductive substrate. In case of a substrate with a poor degree of surface roughness, the contact area is inevitably small to lower the cooling effect by the cooling roller.

Further, the amount of heat to a substrate from a vapor deposition source is the sum of the radiant heat from the vapor deposition source and the latent heat for the evaporated vapor to condense on the substrate, and the ratio of those heats differs depending on the material to be deposited.

Particularly, when materials, such as a high melting point metal and oxide, which have a high melting point and whose vapor pressure rises only at a high temperature of about 2000 degrees, the thermal load applied to a substrate becomes very large, making it extremely difficult to form a film by vapor deposition.

As apparent from the above, there is a difficulty in cooling in vapor deposition on a substrate or metal foil having a poor degree of surface roughness, or a conductive substrate, such as a metal-laminated substrate, or vapor deposition of a high melting point material.

Executing this cooling insufficiently may cause defects, such as deformation of a substrate or production of wrinkles during film deposition, and a change in the composition of a film due to a temperature rise in disposed, and may break a substrate to disable film deposition. Even without those defects, to lower the thermal load on a substrate, the amount of heat from the vapor deposition source 63 needs to be reduced, so that the above problems cannot be avoided unless the film deposition rate is dropped. This makes it difficult to increase the productivity.

By way of contrast, the embodiment can increase the amount of heat absorption by the cooling rollers 7 significantly as compared with the vapor deposition apparatus 300 according to the related art. It is therefore possible to execute sufficient cooling even when using a substrate, metal foil or metal-laminated substrate which has a poor degree of surface roughness, and a deposition material having a high melting point and low vapor deposition pressure, in addition to the aforementioned improvement on the film quality achieved by suppression of gaps. It is also possible to improve the productivity at the time of vapor deposition.

### b. Appearance and Cross-Sectional Structure after Deposition

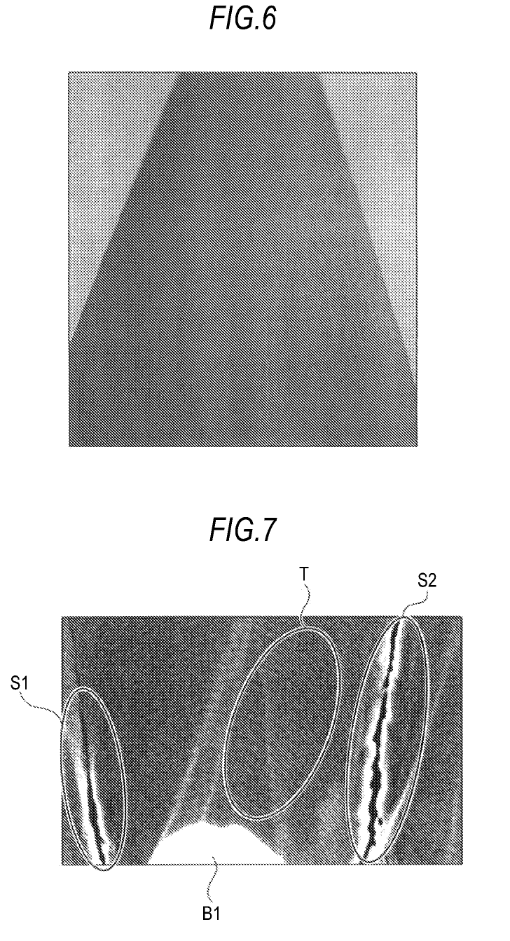

FIG. 5 is a diagram showing the appearance of a substrate and a deposited film when Si is deposited on a metal foil having a thickness of 30 μm and Rz value of 2 μm using the vapor deposition apparatus 300 according to the related art. FIG. 6 is a diagram showing the appearance of a substrate and a deposited film when vapor deposition is performed similarly by using the vapor deposition apparatus 100 according to the embodiment. In both cases, film deposition is performed under the condition of a high thermal load with a deposition speed of 10 μm·m/min.

According to the method of the related art, cooling is carried out from the back side of the deposition surface through a substrate, so that the amount of heat at the time of film deposition cannot be transferred to the cooling roller instantaneously. Because film deposition is performed with the substrate being in contact with the cooling roller, there is friction between the cooling roller and the substrate, so that the widthwise stretching of the substrate cannot be canceled completely. Accordingly, the substrate shown in FIG. 5 has permanent deformation and wrinkles.

When film deposition is performed using the vapor deposition apparatus 100 according to the embodiment, by way of contrast, vapor deposition is performed while the substrate is traveling in the air from one roller to another, eliminating friction and setting the substrate 6 free. Further, because the substrate is traveling between a plurality of cooling rollers, not only heat is absorbed from the back side of the deposition surface through the substrate as in the related art, but also cooling is carried out directly from the vapor deposition surface side, providing a high cooling effect. Accordingly, film deposition can be performed even on a substrate having a rough surface with an Rz value of 2 μm without deformation, such as wrinkles or undulations as shown in FIG. 6.

As has already been described, the embodiment performs multilayer deposition while causing the substrate to travel along the closed-curve traveling path multiple times at a traveling speed faster than that of the related art, thus reducing the amount of heat received by the substrate at a time, and further cools the substrate from both sides thereof, thus reducing the heat-originated load. This can ensure continuous vapor deposition in which the temperature becomes very hot, thus permitting deposition of a thick film with a thickness of the micron order.

When the vapor deposition apparatus 300 according to the related art is used, for example, deposition of a film with a thickness of over 10 μm may deform the substrate due to the thermal load. According to the embodiment, however, even when a film with a thickness of 50 μm is formed, wrinkles, cracks, deformation and the like do not appear.

Because the vapor deposition apparatus 100 according to the embodiment has high cooling performance, vapor deposition of a material with a high melting point and a material with low deposition pressure is possible. Although Si is used as a deposition material according to the embodiment, an oxide can be vapor-deposited. In addition, vapor deposition can be similarly performed with a Co-based magnetic material and on various substrates, such as an aluminum foil, stainless foil, and copper foil, or a substrate with the lamination of those foils.

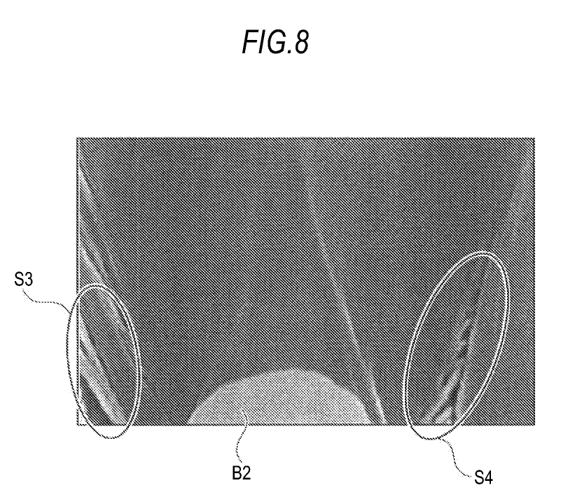

FIG. 7 is an enlarged cross-sectional view showing a film deposited by the vapor deposition apparatus 300 according to the related art and photographed by an SEM (Scanning Electron Microscope). The film deposition was performed under the conditions such that the number of laminated layers was 184, the traveling speed of a substrate was 50 m/min, and the gun power for a beam to vaporize Si as a deposition material was 4.5 kW. FIG. 8 is an enlarged cross-sectional view showing a film with a thickness of 10.2 μm deposited by the vapor deposition apparatus 100 according to the embodiment and photographed by an SEM under the conditions such that the number of laminated layers is 85, the traveling speed of a substrate is 50 m/min, and the gun power is 4.0 kW. B1 and B2 in FIGS. 7 and 8 represent parts of substrates.

While the pattern of laminated layers appears and a gap is produced between deposited layers in a region T in FIG. 7, such a pattern is not seen and a film with uniform quality is shown in FIG. 8 showing the film deposited by the vapor deposition apparatus 100 according to the embodiment.

While there are large gaps between column structures as indicated by S1 and S2 in FIG. 7, the sizes of the gaps can be made significantly smaller as indicated by S3 and S4 in FIG. 8. Because the vapor deposition apparatus according to the embodiment reduces vapor flows which are obliquely incident to a substrate and has high cooling performance, it can perform high-density vapor deposition.

In addition, such high-density vapor deposition can bring about enhanced effects for various products. For example, it is possible to improve the recording density and suppress aging-based deterioration originated from oxidation, and overcome the problem of the wavelength shift for an optical film, which is a change in reflectance caused by time-based progress of oxidation. In addition, more minute deposited films can be obtained for dry-plated products, semiconductor devices, or the like.

### 2. Second Embodiment of Vapor Deposition Method

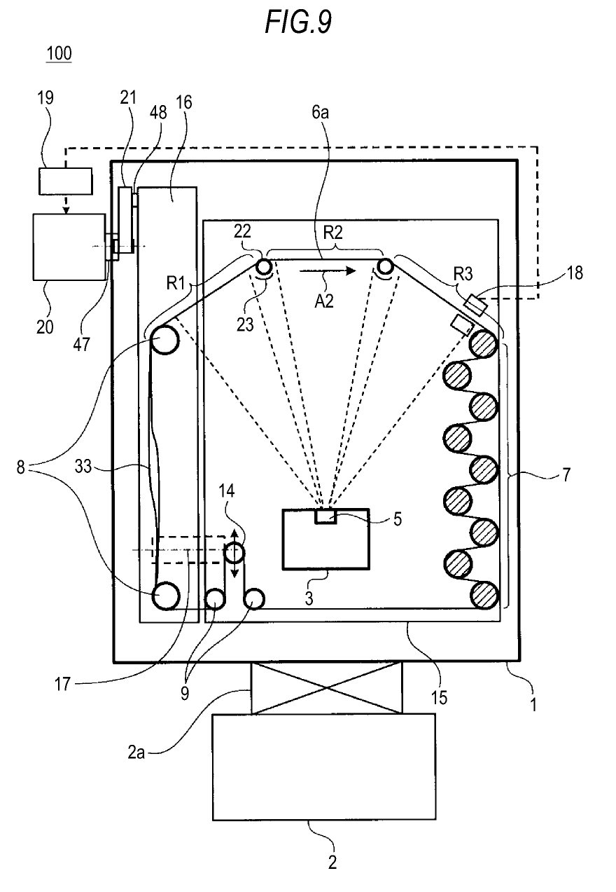

FIG. 9 is a schematic configurational diagram of a vapor deposition apparatus for explaining a vapor deposition method according to the second embodiment of the invention. The vapor deposition apparatus 100 in FIG. 1 can be used directly. Therefore, same reference numerals are given to those portions which are the same as the corresponding portions in FIG. 1 to avoid the redundant description. The embodiment has a similar configured in that of the traveling path of a substrate 6a, those paths where vapor deposition is performed define a concave traveling path with respect to the vapor deposition source 3. The embodiment is also similar in that the substrate 6a is held, as in the embodiment shown in FIG. 1, in the path passing the cooling rollers 7 or the path from the cooling rollers 7 to the guide rollers 9, so that the substrate travels along the overall traveling path with a closed curve pattern.

According to the second embodiment, however, the substrate 6a is twisted half at some position in one cycle of the traveling path. That is, at the time of the substrate 6a is held on the traveling path first, the surface of one end of the substrate 6a is connected with the back side of the other end thereof by welding or the like in such a way as to be continuous surface. This allows the substrate 6a to travel in the direction of an arrow A2 in the closed curve shape like a Möebius ring as a whole. In the example in FIG. 9, a half-twisting position 33 is placed between the guide rollers 8 having a long distance therebetween. As the substrate 6a is twisted half at the position at which the distance between rollers is long, it is possible to make entanglement of the substrate with the rollers difficult. The execution of vapor deposition while allowing the substrate to travel in a Möebius ring state can ensure simultaneous film deposition on both sides of the substrate with a single vapor deposition source.

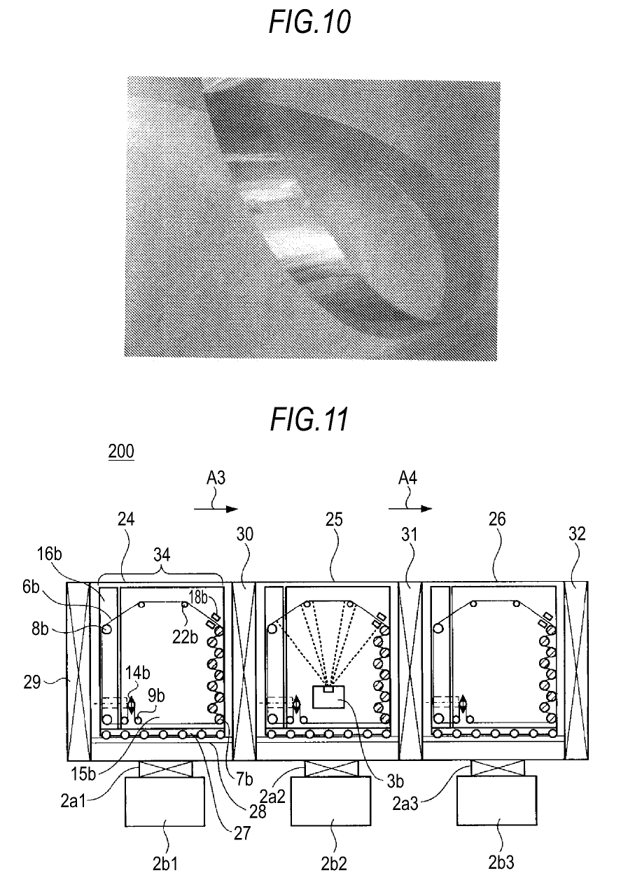

FIG. 10 shows a substrate with a thickness of 20 μm with Cu deposited on booth sides thereof to a thickness of 2.5 μm according to the second embodiment, and shows that vapor deposition can be performed on both sides of a substrate adequately.

When film deposition is performed on both sides of a substrate using the vapor deposition apparatus according to the related art, vapor deposition is performed on the top side and the back side separately. Accordingly, the process including cleaning inside the vacuum tank, resetting of a substrate, vacuuming inside the vacuum tank, melting a deposition material, film deposition, cooling, and feeding air into the vacuum tank needs to be carried out twice. According to the embodiment, by way of contrast, film deposition on both sides of a substrate is carried out at the same time, reducing the time needed for the process by half, which almost doubles the productivity. In addition, the need for only a single vapor deposition source can reduce the cost for the apparatus.

### 3. Second Embodiment of Vapor Deposition Apparatus

FIG. 11 is a schematic configurational diagram of a vapor deposition apparatus 200 according to the second embodiment of the invention.

The vapor deposition apparatus 200 according to the embodiment has three vacuum tanks including a preparation chamber 24, a film deposition chamber 25, a removal chamber 26, partition valves 29, 30, 31, 32 which partition the individual tanks in an openable/closable manner, and a traveling system 34 with a closed curve pattern. Wheels and rails 28 which restrict the moving direction of the wheels are provided as a moving mechanism at the bottom surface in each tank, and through the individual tanks. Further, exhaust sections 2b1, 2b2, 2b3 each including a vacuum pump to vacuum inside each tank are connected to the three tanks via valves 2a1, 2a2, 2a3, respectively.

The closed-curve traveling system 34 includes, for example, a fixed base plate 15b, a movable base plate 16b, guide rollers 8b, 9b, rollers 22b, cooling rollers 7b, a dancer roller 14b, and an edge sensor 18b. Those components may be disposed in a similar pattern to that of the vapor deposition apparatus 100 in FIG. 1, and the traveling path of an elongated substrate 6b has a closed curve pattern. Further, those components are mounted on a pallet 27 as a single unit so as to be moved together with the pallet 27. The unit configuration of the traveling system 34 is not limited to the above type, and may be changed as needed. For example, the moving mechanism that drives the movable base plate 16b, though not illustrated, may have a configuration similar to the one exemplified in FIG. 1. The number of the cooling rollers 7b, the zigzag layout thereof, the presence/absence of the edge sensor 18b, the arrangement thereof, etc. are not limited to those in the example in FIG. 11, and may be changed as needed.

One example of the process of performing vapor deposition with the vapor deposition apparatus 200 will be described below.

First, the valve 29 is opened to insert the closed-curve traveling system 34 mounted on the pallet 27 into the chamber 24. It is preferable to place the substrate 6b on the traveling system 34. Then, the pallet 27 is placed on the rail 28 in the preparation chamber 24, and the interior of the preparation chamber 24 is exhausted by the vacuum pump 2b1.

When the internal state of the preparation chamber 24 reaches a predetermined degree of vacuum, the partition valve 30 is opened to move the traveling system 34 on the rail 28 in the direction of an arrow A3 into the film deposition chamber 25 which is a vacuum tank.

When the traveling system 34 is moved into the film deposition chamber 25, the partition valve 30 is closed again. The vapor deposition source 3b is placed in the film deposition chamber 25, for example, in a movable manner. The vapor deposition source 3b is placed at a predetermined position after movement of the pallet 27. The deposition material is vaporized by heating the vapor deposition source 3b or the like. This achieves vapor deposition on the substrate 6b. According to the second embodiment, the traveling path of the substrate 6b above the vapor deposition source 3b is also set in a concave form with respect to the vapor deposition source 3b, so that vapor flows obliquely incident to the substrate 6b can be reduced, making it possible to achieve gap-less film deposition. Like the first embodiment, the second embodiment can adequately perform cooling, thus ensuring vapor deposition of a material with a high melting point and a material with low deposition pressure.

When film deposition on the substrate 6b is complete, the partition valve 31 is opened to move the traveling system 34 in the direction of an arrow A4 to be moved into the removal chamber 26 which is vacuumed previously. After the partition valve 31 is closed, air is supplied into the removal chamber 26, and the closed-curve traveling system 34 is removed through the valve 32.

In the vapor deposition apparatus 200 according to the embodiment, the preparation chamber 24 and the removal chamber are provided respectively before and after the film deposition chamber 25 where film deposition is performed, and vacuuming inside and air supply into those chambers are performed. Accordingly, the traveling system 34 can be continuously moved from the air-containing state to the vacuum state, vice versa while maintaining the interior of the film deposition chamber 25 in the vacuum state, thus improving the productivity.

In addition, a plurality of film deposition chambers may be provided and coupled together similarly by valves, so that different deposition materials are vapor-deposited in those film deposition chambers, thereby ensuring continuous multilayer film deposition with different types of films.

Because the invention has high cooling performance, as discussed above, it is possible to perform vapor deposition using a substrate, a metal foil, and a metal-laminated substrate which have a poor degree of surface roughness, and a deposition material with a high melting point. In addition, the oblique component of the vapor flows incident to the substrate is reduced, reducing gaps in the deposited film, so that high-density film deposition is possible.

The invention is not limited to the examples described in the foregoing description of the embodiments, and can be modified and changed as needed without departing from the spirit or scope of the invention.

The present application contains subject matter related to that disclosed in Japanese Priority Patent Application JP 2009-134639 filed in the Japan Patent Office on Jun. 4, 2009, the entire contents of which is hereby incorporated by reference.

What is claimed is:

1. A vapor deposition apparatus comprising:
a vacuum tank;
an exhaust section that performs vacuum exhaust in the vacuum tank;
a vapor deposition source disposed in the vacuum tank to vaporize a deposition material; and
a traveling path for allowing an elongated substrate on which the deposition material is deposited to travel along a concave path with respect to the vapor deposition source at least in a region opposing the vapor deposition source.

2. The vapor deposition apparatus according to claim 1, wherein the traveling path is formed to have a closed curve shape.

3. The vapor deposition apparatus according to claim 1, further comprising a plurality of cooling rollers in the traveling path after the substrate is moved out of the region opposing the vapor deposition source,
wherein both sides of the substrate are positioned so as to be contactable with the plurality of cooling rollers.

4. The vapor deposition apparatus according to claim 3, wherein a top side and a back side of the substrate are positioned so as to be alternately contactable with the plurality of cooling rollers.

5. The vapor deposition apparatus according to claim 1, wherein a plurality of guide rollers are disposed at positions substantially equal distances from the vapor deposition source in a direction for the deposition material to be scattered, and a traveling path for allowing the substrate to travel in a concave pattern with respect to the vapor deposition source is provided.

6. The vapor deposition apparatus according to claim 5, wherein the guide rollers are provided at positions off a direction directly above the vapor deposition source.

7. The vapor deposition apparatus according to claim 5, wherein the guide rollers are provided with cover members.

8. The vapor deposition apparatus according to claim 1, further comprising a roller provided on the traveling path of the substrate so as to be movable in a direction intersecting a top surface of the substrate.

9. The vapor deposition apparatus according to claim 1, further comprising:
a sensor that detects an edge of the substrate; and
a moving mechanism that moves at least one of rollers forming the traveling path in a direction substantially along a top surface of the substrate based on a detected position of the edge.

10. The vapor deposition apparatus according to claim 1, further comprising:
a plurality of vacuum tanks;
an openable and closable valve that connects the plurality of vacuum tanks to one another;
a vapor deposition source provided in at least one of the vacuum tanks; and
a moving mechanism that moves the traveling path between the plurality of vacuum tanks.

11. A vapor deposition method comprising:
a substrate holding step of holding an elongated substrate along a concave path with respect to a vapor deposition source at least in a region opposing the vapor deposition source; and
a vapor deposition step of scattering a deposition material from the vapor deposition source to perform vapor deposition on the substrate while causing the substrate to travel along the path.

12. The vapor deposition method according to claim 11, wherein the path for holding the substrate is set in a closed curve shape, and
in the substrate holding step, the substrate is held in a closed curve shape in a Möebius ring shape in the path.

13. The vapor deposition method according to claim 11, wherein in the vapor deposition step, a traveling speed of the substrate is set to 50 m/min or greater and 200 m/min or less.

14. The vapor deposition method according to claim 11, wherein in the vapor deposition step, vapor deposition of the deposition material is performed on the substrate multiple times to laminate layers formed of the deposition material.
